(19) United States
(12) Patent Application Publication
(10) Pub. No.: US 2025/0194438 A1
(43) Pub. Date: Jun. 12, 2025

(54) INFORMATION READING METHOD OF SELF-SELECTING MEMORY DEVICE

(71) Applicant: Samsung Electronics Co., Ltd., Suwon-si (KR)

(72) Inventors: Youngjae KANG, Suwon-si (KR); Changseung LEE, Suwon-si (KR); Kiyeon YANG, Suwon-si (KR); Hajun SUNG, Suwon-si (KR); Zhe WU, Suwon-si (KR); Minwoo CHOI, Suwon-si (KR)

(73) Assignee: Samsung Electronics Co., Ltd., Suwon-si (KR)

(21) Appl. No.: 18/742,371

(22) Filed: Jun. 13, 2024

(30) Foreign Application Priority Data
Dec. 12, 2023 (KR) 10-2023-0180099

(51) Int. Cl. H10N 70/20; G11C 16/26; H10N 70/00

(52) U.S. Cl. CPC H10N 70/231; G11C 16/26; H10N 70/826

(57) ABSTRACT

Provided are information reading methods of a self-selecting memory device, which includes a first electrode, a second electrode, and a memory layer therebetween, the memory layer including a chalcogenide-based material, having Ovonic threshold switching characteristics, and configured to have a threshold voltage that changes to a set threshold voltage or a reset threshold voltage higher than the set threshold voltage according to polarity and intensity of a voltage applied to the memory layer. An information reading method may include reading a data value stored in the memory layer by applying, to the memory layer as a read voltage, a voltage lower than the set threshold voltage.

### CROSS-REFERENCE TO RELATED APPLICATION

This application is based on and claims priority under 35 U.S.C. § 119 to Korean Patent Application No. 10-2023-0180099, filed on Dec. 12, 2023, in the Korean Intellectual Property Office, the disclosure of which is incorporated by reference herein in its entirety.

### BACKGROUND

### 1. Field

The disclosure relates to information reading methods of a self-selecting memory device.

### 2. Description of the Related Art

As electronic products become lighter, thinner, and slimmer, the demand for high integration of memory devices is increasing. A memory device having a cross-point structure has a structure in which word lines and bit lines vertically cross each other and memory cells are arranged in areas where the word lines and the bit lines vertically cross each other. Such a structure has an advantage of having small memory cells in a plan view. In general, a memory cell of a memory device having a cross-point structure includes a 2-terminal selector and a memory device, which are connected in series to each other, so as to prevent a sneak current between neighboring memory cells. Recently, a self-selecting memory device that simultaneously performs a selector function and a memory device function has been developed.

### SUMMARY

Provided is an information reading method of a self-selecting memory device.

Additional aspects will be set forth in part in the description which follows and, in part, will be apparent from the description, or may be learned by practice of the presented example embodiments of the disclosure.

According to an example embodiment of the disclosure, provided is an information reading method of a self-selecting memory device, the self-selecting memory device including a first electrode, a second electrode r and a memory layer therebetween, the memory layer including a chalcogenide-based material, having Ovonic threshold switching characteristics, and configured to have a threshold voltage that changes to a set threshold voltage or a reset threshold voltage higher than the set threshold voltage according to polarity and intensity of a voltage applied to the memory layer. The information reading method may include reading a data value stored in the memory layer by applying, to the memory layer as a read voltage, a voltage lower than the set threshold voltage.

A level of the read voltage may be about 40% to about 90% of a level of the set threshold voltage.

The level of the read voltage may be about 60% to about 80% of the level of the set threshold voltage.

The reading may read the data value stored in the memory layer by measuring a current flowing through the memory layer at the read voltage.

When the current flowing through the memory layer is measured as a relatively high current value, the memory layer may be read as set, and when the current flowing through the memory layer is measured as a relatively low current value, the memory layer may be read as reset.

The relatively high current value may be 10 times or more the relatively low current value.

A polarity of the read voltage may be positive (+).

The memory layer may include a chalcogen element including at least one of Se, Te, and S, and at least one of Ge, As, or Sb.

The memory layer may further include at least one of In, Al, C, B, Sr, Ga, O, N, Si, Ca, or P.

According to another aspect of the disclosure, provided is an information reading method of a self-selecting memory device, the self-selecting memory device including a first electrode, a second electrode, and a memory layer therebetween, the memory layer including a chalcogenide-based material, having Ovonic threshold switching characteristics, and configured to have a threshold voltage that changes to a set threshold voltage or a reset threshold voltage higher than the set threshold voltage according to polarity and intensity of a voltage applied to the memory layer. The information ready method may include reading a data value stored in the memory layer by applying, to the memory layer as a read voltage, a voltage at a critical point immediately before a slope of a set curve changes rapidly, the voltage at the critical point being lower than the set threshold voltage in a current-voltage characteristic curve for the memory layer.

A level of the read voltage may be about 80% to about 95% of a level of the set threshold voltage.

The reading may read the data value stored in the memory layer by measuring a value of change of a current flowing through the memory layer at the read voltage.

When the value of change of the current measured in the memory layer is a relatively high value, the memory layer may be read as set, and when the value of change of the current measured in the memory layer is a relatively low value, the memory layer may be read as reset.

A polarity of the read voltage may be positive (+).

According to another aspect of the disclosure, provided is an information reading method of a self-selecting memory device, the self-selecting memory device including a first electrode, a second electrode, and a memory layer therebetween, the memory layer including a chalcogenide-based material, having Ovonic threshold switching characteristics, and configured to have a threshold voltage that changes to a set threshold voltage or a reset threshold voltage higher than the set threshold voltage according to polarity and intensity of a voltage applied to the memory layer. The information reading method may include reading a data value stored in the memory layer by sequentially applying, to the memory layer as a read voltage, rectangular pulse voltages whose levels gradually increase at a voltage lower than the set threshold voltage.

When a certain pulse voltage applied to the memory layer is measured as the set threshold voltage, the memory layer may be read as set, and when the certain pulse voltage applied to the memory layer is measured as the reset threshold voltage, the memory layer may be read as reset.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 is a cross-sectional view schematically illustrating a self-selecting memory device according to an example embodiment;

FIG. 2 is a graph showing voltage-current characteristics of a memory layer in the self-selecting memory device illustrated in FIG. 1;

FIG. 3A is a graph showing bias voltages for a set operation and a read operation in the self-selecting memory device illustrated in FIG. 1;

FIG. 3B is a graph showing bias voltages for a reset operation and a read operation in the self-selecting memory device illustrated in FIG. 1;

FIG. 4 is a diagram for describing an information reading method of the self-selecting memory device illustrated in FIG. 1, according to an example embodiment;

FIG. 5 is a voltage plot illustrating a relationship between a threshold voltage and a read pulse voltage in the information reading method illustrated in FIG. 4, according to an example embodiment;

FIG. 6 is a diagram for describing an information reading method of the self-selecting memory device illustrated in FIG. 1, according to an example embodiment;

FIG. 7A and FIG. 7B are diagrams for describing an information reading method of the self-selecting memory device illustrated in FIG. 1, according to an example embodiment;

FIG. 8 is a perspective view schematically illustrating a self-selecting memory device according to an example embodiment;

FIG. 9 is an enlarged view of a memory cell in the self-selecting memory device illustrated in FIG. 8;

FIG. 10 is a plan view illustrating an operation of selecting a specific memory cell in the self-selecting memory device illustrated in FIG. 8;

FIG. 11 is a conceptual diagram schematically illustrating a device architecture applicable to an electronic device;

FIG. 12 is a block diagram of a memory system according to an example embodiment; and

FIG. 13 is a block diagram illustrating a neuromorphic apparatus and an external device connected thereto, according to an example embodiment.

### DETAILED DESCRIPTION

Reference will now be made in detail to some example embodiments, which are illustrated in the accompanying drawings, wherein like reference numerals refer to like elements throughout. In this regard, the present example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, some example embodiments will be described in detail with reference to the accompanying drawings. In the following drawings, the same reference numerals denote the same elements, and the size of each element in the drawings may be exaggerated for clarity and convenience of explanation. Embodiments described herein are merely examples and various modifications may be made thereto from these example embodiments.

Hereinafter, the terms “above” or “on” may include not only those that are directly above, below, left, or right in a contact manner, but also those that are above, below, left, or right in a non-contact manner. The singular forms “a,” “an,” and “the” as used herein are intended to include the plural forms as well unless the context clearly indicates otherwise. It will be understood that the terms “comprise,” “include,” or “have” as used herein specify the presence of stated elements, but do not preclude the presence or addition of one or more other elements.

The use of the term “the” and similar demonstratives may correspond to both the singular and the plural. Operations constituting methods may be performed in any suitable order unless otherwise indicated herein or otherwise clearly contradicted by context, and are not necessarily limited to the stated order.

Also, the terms such as “unit” and “module” described in the specification mean units that process at least one function or operation, and may be implemented as hardware, software, or a combination of hardware and software.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Connecting lines or connecting members illustrated in the drawings are intended to represent example functional relationships and/or physical or logical connections between the various elements. It should be noted that many alternative or additional functional relationships, physical connections or logical connections may be present in a practical device.

The use of all illustrations or illustrative terms in the example embodiments is simply to describe the technical ideas in detail, and the scope of the inventive concepts is not limited by the illustrations or illustrative terms unless they are limited by claims.

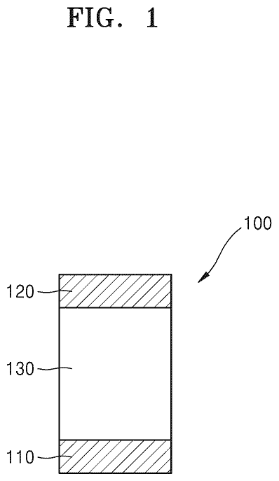

FIG. 1 is a cross-sectional view schematically illustrating a self-selecting memory device 100 according to an example embodiment.

Referring to FIG. 1, the self-selecting memory device 100 may include a first electrode 110, a second electrode 120 apart from the first electrode 110 and arranged to face the first electrode 110, and a memory layer 130 arranged between the first electrode 110 and the second electrode 120.

The first electrode 110 and the second electrode 120 may function to apply a voltage to the memory layer 130. To this end, each of the first electrode 110 and the second electrode 120 may include metal, conductive metal nitride, conductive metal oxide, or any combination thereof. For example, each of the first electrode 110 and the second electrode 120 may include at least one of titanium nitride (TiN), titanium silicon nitride (TiSiN), titanium carbon nitride (TiCN), titanium carbon silicon nitride (TiCSiN), titanium aluminum nitride (TiAlN), tantalum (Ta), tantalum nitride (TaN), tantalum silicon nitride (TaSiN), tantalum aluminum nitride (TaAlN), tungsten silicide (WSi), titanium tungsten (TiW), molybdenum nitride (MoN), niobium nitride (NbN), titanium boron nitride (TiBN), zirconium silicon nitride (ZrSiN), tungsten silicon nitride (WSiN), tungsten boron nitride (WBN), zirconium aluminum nitride (ZrAlN), molybdenum aluminum nitride (MoAlN), titanium aluminum (TiAl), titanium oxynitride (TiON), titanium aluminum oxynitride (TiAlON), tungsten oxynitride (WON), tantalum oxynitride (TaON), silicon carbon (SIC), silicon carbon nitride (SiCN), carbon nitride (CN), tantalum carbon nitride (TaCN), tungsten (W), tungsten nitride (WN), carbon (C), or any combination thereof.

The memory layer 130 may have Ovonic threshold switching (OTS) characteristics. That is, the memory layer 130 has a high resistance state when a voltage lower than a threshold voltage is applied thereto and a low resistance state when a voltage higher than the threshold voltage is applied thereto. In addition, the memory layer 130 may have memory characteristics in which a threshold voltage shifts according to the polarity and intensity of a bias voltage applied thereto. Accordingly, the memory layer 130 may have characteristics of a self-selecting memory capable of performing both a memory function and a selector function.

The memory layer 130 may include a chalcogenide-based material. For example, the memory layer 130 may include a chalcogen element including at least one of Se, Te, or S, and at least one of Ge, As, or Sb. In addition, the memory layer 130 may further include at least one of In, Al, C, B, Sr, Ga, O, N, Si, Ca, P, or S. For example, the memory layer 130 may include at least one of GeAsSe, GeAsSeIn, GeAsSeSIn, GeAsSeSb, GeAsSeTe, GeAsSeAl, GeAsSeAlIn, GeSbSe, or GeSbSeN.

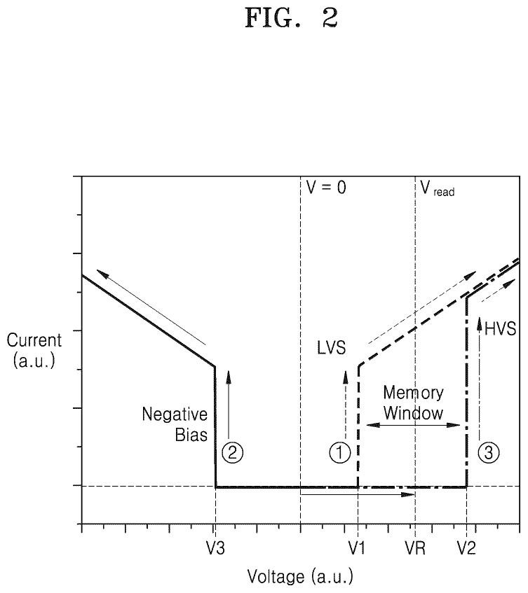

FIG. 2 is a graph showing voltage-current characteristics of the memory layer 130 in the self-selecting memory device 100 illustrated in FIG. 1, according to an example embodiment.

Referring to FIG. 2, the memory layer 130 may have a first state (a low Vth state (LVS)) in which the threshold voltage is relatively low and a second state (a high Vth state (HVS)) in which the threshold voltage is relatively high. For example, in the first state, the threshold voltage of the memory layer 130 may be a first voltage V1, and in the second state, the threshold voltage of the memory layer 130 may be a second voltage V2 that is higher than the first voltage V1.

In a case where the memory layer 130 is in the first state, when a voltage lower than the first voltage V1 is applied to the memory layer 130, almost no current flows between both ends of the memory layer 130, and when a voltage higher than the first voltage V1 is applied to the memory layer 130, the memory layer 130 is turned on and a current flows through the memory layer 130. In addition, in a case where the memory layer 130 is in the second state, when a voltage lower than the second voltage V2 is applied to the memory layer 130, almost no current flows between both ends of the memory layer 130, and when a voltage higher than the second voltage V2 is applied to the memory layer 130, the memory layer 130 is turned on and a current flows through the memory layer 130.

In a case where the memory layer 130 is in the first state, when a negative (−) bias voltage is applied to the memory layer 130, the threshold voltage of the memory layer 130 may increase and the memory layer 130 may change to the second state. For example, when a negative third voltage V3 is applied to the memory layer 130, the memory layer 130 may change to the second state. This operation may be referred to as a “reset” operation. In addition, in a case where the memory layer 130 is in the second state, when a positive (+) bias voltage higher than the second voltage V2 is applied to the memory layer 130, the threshold voltage of the memory layer 130 may decrease and the memory layer 130 may change to the first state. This operation may be referred to as a “set” operation. A difference between the second voltage V2, which is a reset threshold voltage, and the first voltage V1, which is a set threshold voltage, corresponds to a memory window.

As described above, the memory layer 130 of the self-selecting memory device 100 may have OTS characteristics and simultaneously have memory characteristics in which the threshold voltage changes. For example, the threshold voltage of the memory layer 130 may be shifted according to the polarity of the bias voltage applied to the memory layer 130. In this regard, the self-selecting memory device 100 may have polarity-dependent threshold voltage shift characteristics.

For information reading of the self-selecting memory device 100, for example, a voltage between the first voltage V1, which is the set threshold voltage, and the second voltage V2, which is the reset threshold voltage, may be selected as a read voltage VR. In this case, when the read voltage VR is applied to the memory layer 130 while the memory layer 130 is in the first state, a current flows through the memory layer 130. At this time, a data value stored in the memory layer 130 may be defined as “1.” When the read voltage VR is applied to the memory layer 130 while the memory layer 130 is in the second state, almost no current flows through the memory layer 130. At this time, a data value stored in the memory layer 130 may be defined as “0.” In other words, the data value stored in the memory layer 130 may be read by measuring the current flowing through the memory layer 130 while the read voltage VR is applied to the memory layer 130.

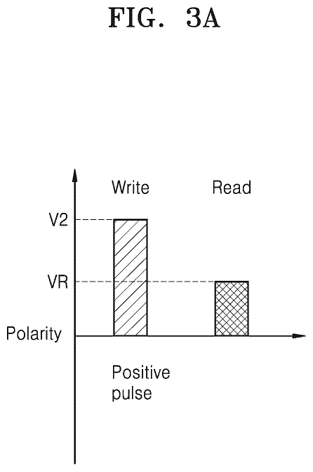

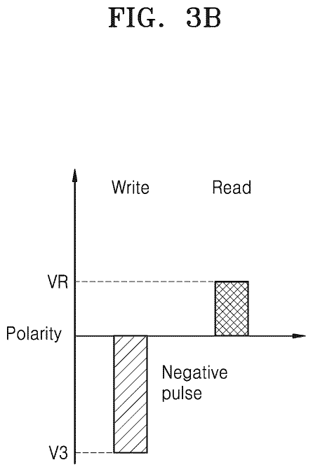

FIG. 3A is a graph showing the bias voltages for the set operation and the read operation in the self-selecting memory device 100 illustrated in FIG. 1, according to an example embodiment. FIG. 3B is a graph showing the bias voltages for the reset operation and the read operation in the self-selecting memory device 100 illustrated in FIG. 1, according to an example embodiment. FIGS. 3A and 3B illustrate a case where the positive read voltage VR between the first voltage V1 and the second voltage V2 is applied to the memory layer 130.

Referring to FIG. 3A, in the set operation, the positive bias voltage higher than the second voltage V2 may be applied to the memory layer 130. Then, the threshold voltage of the memory layer 130 may be shifted to the first voltage V1. Subsequently, in the read operation, the positive read voltage VR between the first voltage V1 and the second voltage V2 may be applied to the memory layer 130. When the read voltage VR is applied to the memory layer 130, the memory layer 130 may be turned on.

Referring to FIG. 3B, in the reset operation, the negative bias voltage, that is, the third voltage V3 may be applied to the memory layer 130. An absolute value of the third voltage V3 may be approximately equal to the second voltage V2, or may be slightly greater than or less than the second voltage V2. Then, the threshold voltage of the memory layer 130 may be shifted to the second voltage V2 that is higher than the first voltage V1. Subsequently, in the read operation, the positive read voltage VR between the first voltage V1 and the second voltage V2 may be applied to the memory layer 130. When the read voltage VR is applied to the memory layer 130, the memory layer 130 may be turned off.

As described above, the method of reading information by selecting the voltage between the first voltage V1, which is the set threshold voltage, and the second voltage V2, which is the reset threshold voltage, as the read voltage VR may be a destructive reading method in which the read data may be destroyed. That is, when a read voltage having a polarity opposite to a polarity of a write voltage is used, read disturb may occur, which weakens the polarity of the write voltage. In order to recover the weakened polarity, a refresh pulse has to be applied.

Hereinafter, non-destructive information reading methods of the self-selecting memory device 100 illustrated in FIG. 1 according to some example embodiments are described.

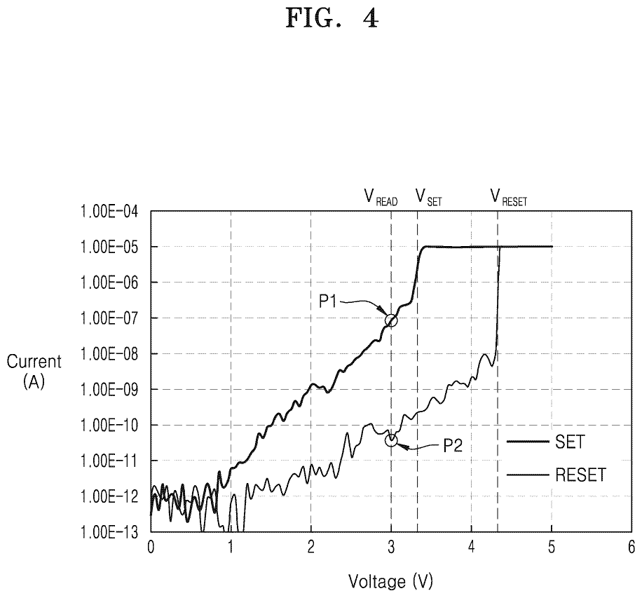

FIG. 4 is a diagram for describing an information reading method of the self-selecting memory device 100 illustrated in FIG. 1, according to an example embodiment. FIG. 4 illustrates a read voltage V_{READ} for information reading of the self-selecting memory device 100 in a current-voltage (I-V) characteristic curve of the memory layer 130.

As described above, the memory layer 130 has OTS characteristics and may be configured so that the threshold voltage thereof changes according to the polarity and intensity of the voltage applied thereto. The threshold voltage may change to a set threshold voltage V_{SET} or a reset threshold voltage V_{RESET} according to the polarity and intensity of the voltage applied to the memory layer 130. The set threshold voltage V_{SET} is lower than the reset threshold voltage V_{RESET}.

FIG. 4 illustrates an I-V characteristic curve (a set curve) implemented by the set operation of the memory layer 130 and an I-V characteristic curve (a reset curve) implemented by the reset operation of the memory layer 130.

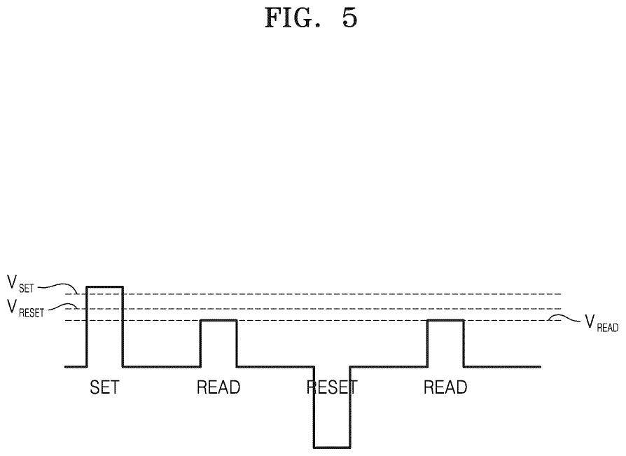

FIG. 5 is a voltage plot illustrating a relationship between a threshold voltage and a read pulse voltage in the information reading method illustrated in FIG. 4, according to an example embodiment. FIG. 5 illustrates a write pulse voltage for a set operation, a write pulse voltage for a reset operation, a read pulse voltage V_{READ}, a set threshold voltage V_{SET}, and a reset threshold voltage V_{RESET}.

Referring to FIGS. 4 and 5, a data value stored in the memory layer 130 may be read by applying a voltage lower than the set threshold voltage V_{SET} to the self-selecting memory device 100 as the read voltage V_{READ}. For example, the level of the read voltage V_{READ} may be about 40% to about 90% of the level of the set threshold voltage V_{SET}. For example, the level of the read voltage V_{READ} may be about 60% to about 80% of the level of the set threshold voltage V_{SET}. The read voltage V_{READ} may be a voltage with a positive polarity. However, the disclosure is not limited thereto and the read voltage V_{READ} may be a voltage with a negative polarity.

A data value stored in the memory layer 130 may be read by measuring a current flowing through the memory layer 130 while a voltage lower than the set threshold voltage V_{SET} is applied to the self-selecting memory device 100 as the read voltage V_{READ}. For example, as illustrated in FIG. 4, a current value at a first point P1 where the read voltage V_{READ} (lower than the set threshold voltage V_{SET}) meets the set curve may be significantly great, compared to a current value at a second point P2 where the read voltage V_{READ} meets the reset curve. For example, the current value at the first point P1 where the read voltage V_{READ} meets the set curve may be about 10 times or more the current value at the second point P2 where the read voltage V_{READ} meets the reset curve.

It is confirmed that a difference between the current value at the first point P1 and the current value at the second point P2 measured at the read voltage V_{READ} lower than the set threshold voltage V_{SET} is significantly greater. Therefore, it may be determined whether the memory layer 130 is in the set state or in the reset state by applying a voltage lower than the set threshold voltage V_{SET} (specifically, about 40% to about 90% of the set threshold voltage V_{SET}) to the self-selecting memory device 100 as the read voltage V_{READ} and measuring the current flowing through the memory layer 130. That is, when the current flowing through the memory layer 130 is measured as a relatively high current value, the memory layer 130 may be read as “set,” and when the current flowing through the memory layer 130 is measured as a relatively low current value, the memory layer 130 may be read as “reset.” Furthermore, by setting the read voltage V_{READ} to a voltage lower than the set threshold voltage V_{SET}, non-destructive reading is possible because information recorded on the memory layer 130 is not affected by reading.

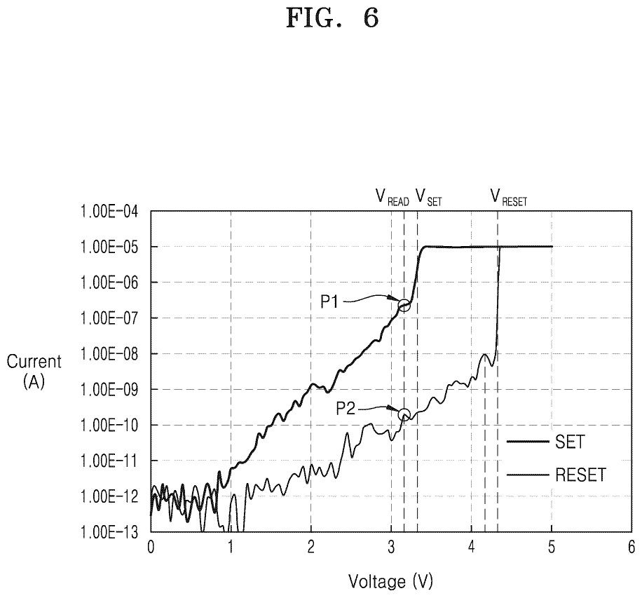

FIG. 6 is a diagram for describing an information reading method of the self-selecting memory device 100 illustrated in FIG. 1, according to an example embodiment. FIG. 6 illustrates a read voltage V_{READ} for information reading of the self-selecting memory device 100 in an I-V characteristic curve of the memory layer 130.

As described above, the memory layer 130 has OTS characteristics and may be configured so that a threshold voltage thereof changes according to the polarity and intensity of a voltage applied thereto. The threshold voltage may change to a set threshold voltage V_{SET} or a reset threshold voltage V_{RESET} according to the polarity and intensity of the voltage applied to the memory layer 130. The set threshold voltage V_{SET} is lower than the reset threshold voltage V_{RESET}.

FIG. 6 illustrates an I-V characteristic curve (a set curve) implemented by a set operation of the memory layer 130 and an I-V characteristic curve (a reset curve) implemented by a reset operation of the memory layer 130.

Referring to FIG. 6, a data value stored in the memory layer 130 may be read by applying the read voltage V_{READ} lower than the set threshold voltage V_{SET} to the self-selecting memory device 100. The read voltage V_{READ} may be a voltage with a positive polarity. However, the disclosure is not limited thereto and the read voltage V_{READ} may be a voltage with a negative polarity.

For example, FIG. 6 illustrates a critical point in the set curve. The critical point represents a point in the set curve immediately before the slope of the set curve changes rapidly. In other words, the critical point represents a first point P1 where the voltage that is lower than the set threshold voltage V_{SET} and immediately before the slope of the set curve changes rapidly meets the set curve. The level of the voltage at the critical point (the first point P1) may be, for example, about 80% to about 95% of the level of the set threshold voltage V_{SET}. A data value stored in the memory layer 130 may be read by measuring a value of change of a current flowing through the memory layer 130 while the voltage at the critical point (the first point P1) is applied to the self-selecting memory device 100 as the read voltage V_{READ}.

For example, referring to FIG. 6, a slope value of the set curve at the first point P1 where the read voltage V_{READ} (e.g., the voltage at the critical point) meets the set curve may be significantly great, compared to a slope value of the reset curve at the second point P2 where the read voltage V_{READ} (e.g., the voltage at the critical point) meets the reset curve. For example, the slope value of the set curve at the first point P1 may be about 10 times or more the slope value of the reset curve at the second point P2. The slope value of the set curve represents the value of change of the current according to the read voltage V_{READ} at the first point P1, and the slope value of the reset curve represents the value of change of the current according to the read voltage V_{READ} at the second point P2.

As described above, it may be confirmed that a difference between the slope value of the set curve and the slope value of the reset curve measured by applying the voltage at the critical point (the first point P1) (e.g., the voltage lower than the set threshold voltage V_{SET}) to the self-selecting memory device 100 as the read voltage V_{READ} is significantly great. Therefore, it may be determined whether the memory layer 130 is in the set state or in the reset state by setting the read voltage V_{READ} to a voltage lower than the set threshold voltage V_{SET} (e.g., setting the read voltage V_{READ} to about 80% to about 95% of the set threshold voltage V_{SET}) and measuring the value of change of the current flowing through the memory layer 130. That is, when the value of change of the current flowing through the memory layer 130 is measured as a relatively high value, the memory layer 130 may be read as “set,” and when the value of change of the current flowing through the memory layer 130 is measured as a relatively low value, the memory layer 130 may be read as “reset.” Furthermore, by setting the read voltage V_{READ} to a voltage lower than the set threshold voltage V_{SET}, non-destructive reading is possible because information recorded on the memory layer 130 is not affected by reading.

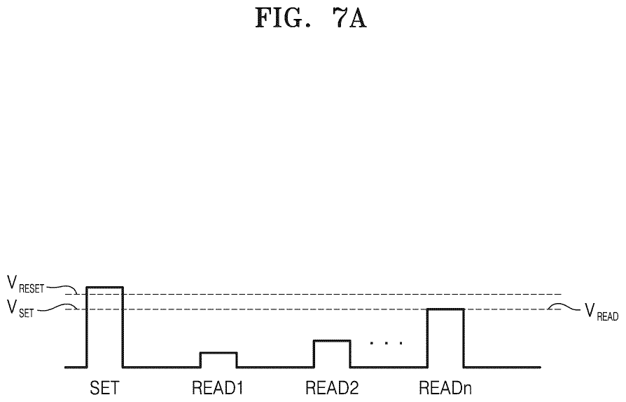

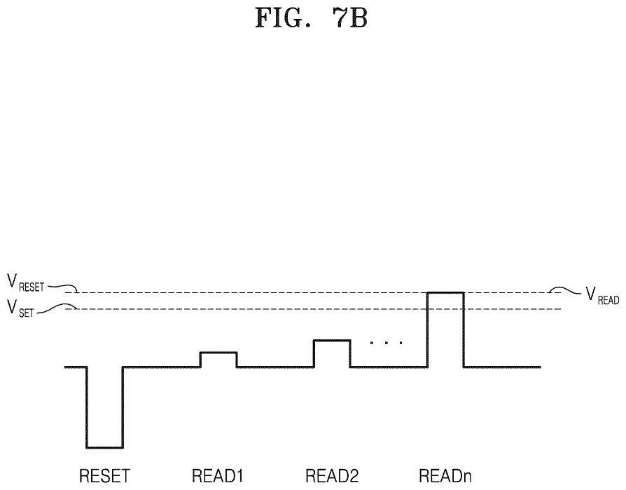

FIG. 7A and FIG. 7B are diagrams for describing an information reading method of the self-selecting memory device 100 illustrated in FIG. 1, according to an example embodiment.

FIG. 7A illustrates a reset threshold voltage V_{RESET}, a set threshold voltage V_{SET}, a read voltage V_{READ}, a write pulse voltage for a set operation, and rectangular pulse voltages READ1, READ2, . . . , READn.

Referring to FIG. 7A, the rectangular pulse voltages READ1, READ2, . . . , READn whose levels gradually increase from a voltage lower than the set threshold voltage V_{SET} are sequentially applied to the memory layer 130 as the reading voltage. Through such a voltage application process, a certain pulse voltage (e.g., READn) applied to the memory layer 130 may be measured as the set threshold voltage V_{SET}. In this case, the memory layer 130 may be read as “set,” and the certain pulse voltage (e.g., READn) applied to the memory layer 130 may be the read voltage V_{READ} for “set” reading.

FIG. 7B illustrates a reset threshold voltage V_{RESET}, a set threshold voltage V_{SET}, a read voltage V_{READ}, a write pulse voltage for a reset operation, and rectangular pulse voltages READ1, READ2, . . . , READn.

The rectangular pulse voltages READ1, READ2, . . . , READn whose levels gradually increase from a voltage lower than the set threshold voltage V_{SET} are sequentially applied to the memory layer 130 as the reading voltage. Through such a voltage application process, a certain pulse voltage (e.g., READn) applied to the memory layer 130 may be measured as the reset threshold voltage V_{RESET}. In this case, the memory layer 130 may be read as “reset,” and the certain pulse voltage (e.g., READn) applied to the memory layer 130 may be the read voltage V_{READ} for “reset” reading.

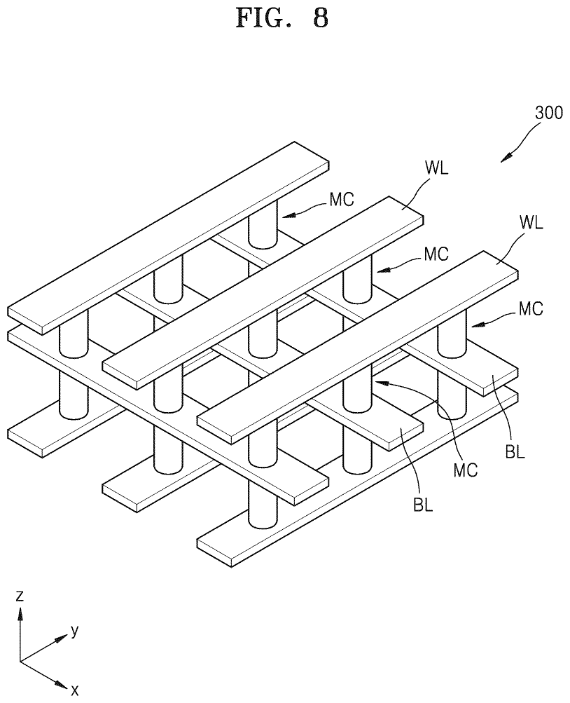

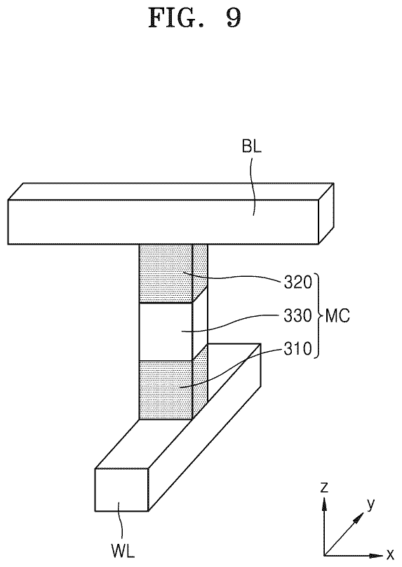

FIG. 8 is a cross-sectional view schematically illustrating a self-selecting memory device 300 according to an example embodiment. FIG. 9 is an enlarged view of a memory cell MC in the self-selecting memory device 300 illustrated in FIG. 8.

Referring to FIGS. 8 and 9, the self-selecting memory device 300 may have a three-dimensional cross-point structure. For example, the self-selecting memory device 300 may include a plurality of bit lines BL extending in a first direction (e.g., an x-axis direction), a plurality of word lines WL extending in a second direction (e.g., a y-axis direction) crossing the first direction, and memory cells MC provided at points where the bit lines BL and the word lines WL cross each other.

The memory cell MC may correspond to the self-selecting memory device 100 illustrated in FIG. 1. For example, a lower electrode 310 and an upper electrode 320 may correspond to the first electrode 110 and the second electrode 120 of the self-selecting memory device 100 illustrated in FIG. 1, respectively. A memory layer 330 may correspond to the memory layer 130 of the self-selecting memory device 100 illustrated in FIG. 1. Accordingly, the memory layer 330 may have the same characteristics as the memory layer 130 of the self-selecting memory device 100 illustrated in FIG. 1. In such a structure, the memory cell MC may be driven by a potential difference between the word line WL and the bit line BL, which are connected to both ends of the memory cell MC, respectively. Because the method of reading information stored in each of the memory cells MC has been described in detail in the aforementioned example embodiments, descriptions thereof are omitted.

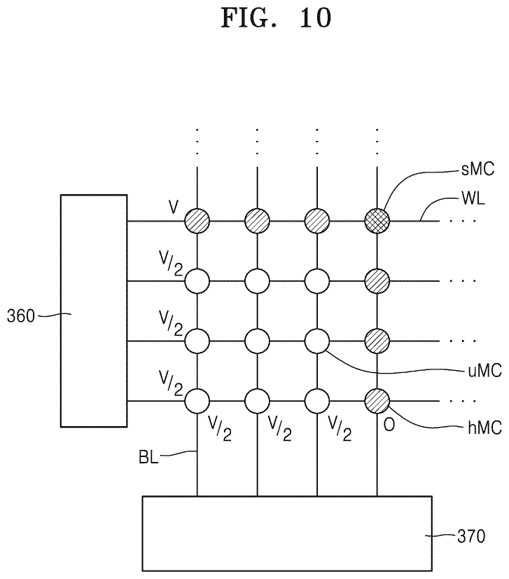

FIG. 10 is a plan view illustrating an operation of selecting a specific memory cell MC in the self-selecting memory device 300 illustrated in FIG. 8.

Referring to FIG. 10, the self-selecting memory device 300 may further include a row decoder 360 that selectively supplies a voltage to the word lines WL, and a column decoder 370 that selectively supplies a voltage to the bit lines BL. When a voltage of V is applied to one selected memory cell sMC that is selected from among the memory cells MC, the row decoder 360 may provide a voltage of V to a word line WL connected to the selected memory cell sMC and provide a voltage of V/2 to the remaining word lines WL. At this time, the column decoder 370 may provide a voltage of 0 V to a bit line BL connected to the selected memory cell sMC and provide a voltage of V/2 to the remaining bit lines BL.

A potential difference between the word line WL and the bit line BL of the selected memory cell sMC becomes V. On the other hand, a potential difference between the word line WL to which a voltage of V/2 is provided and the bit line BL to which a voltage of V/2 is provided becomes 0 V. Accordingly, no voltage is applied to an unselected memory cell uMC arranged between a word line WL and a bit line BL that are not connected to the selected memory cell sMC. On the other hand, a voltage of V/2 may be applied to both ends of a semi-selected memory cell hMC connected to the same word line WL as the selected memory cell sMC or connected to the same bit line BL as the selected memory cell sMC. Because each of the memory cells MC is the self-selecting memory device as described above, even when a voltage of V/2 is applied to the semi-selected memory cell hMC adjacent to the selected memory cell sMC, the semi-selected memory cell hMC is not turned on. Thus, substantially no sneak current occurs.

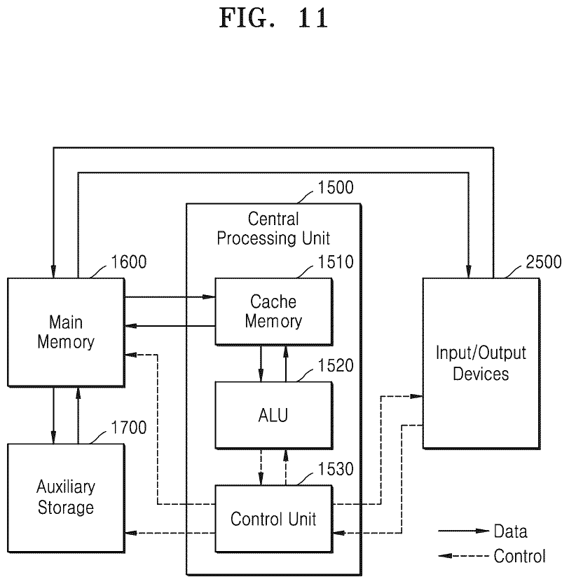

The self-selecting memory devices 10 and 300 according to the aforementioned example embodiments may be used to store data in various electronic devices. FIG. 11 is a conceptual diagram schematically illustrating a device architecture applicable to an electronic device, according to an example embodiment.

Referring to FIG. 11, a cache memory 1510, an arithmetic logic unit (ALU) 1520, and a control unit 1530 may constitute a central processing unit (CPU) 1500. The cache memory 1510 may include a static random access memory (SRAM). Apart from the CPU 1500, a main memory 1600 and an auxiliary storage 1700 may be provided. The main memory 1600 may include a dynamic random access memory (DRAM) device, and the auxiliary storage 1700 may include the self-selective memory devices 100 and 300 described above. In some cases, the device architecture may be implemented in a form in which computing unit elements and memory unit elements are adjacent to each other on a single chip, without distinction of sub-units. In some cases, the device architecture may further include input/output devices 2500.

The self-selecting memory devices 100 and 300 according to the aforementioned example embodiments may be implemented as chip-type memory blocks and used as a neuromorphic computing platform, or may be used to construct a neural network.

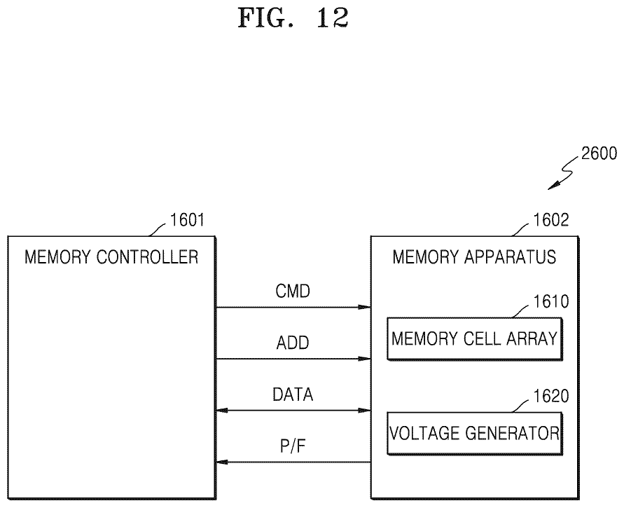

FIG. 12 is a block diagram of a memory system 2600 according to an example embodiment.

Referring to FIG. 12, the memory system 2600 may include a memory controller 1601 and a memory apparatus 1602. The memory controller 1601 may perform a control operation on the memory apparatus 1602. For example, the memory controller 1601 may provide, to the memory apparatus 1602, an address ADD and a command CMD for performing program (or write), read, and/or erase operations on the memory apparatus 1602. In addition, data for the program operation and the read operation may be transmitted between the memory controller 1601 and the memory apparatus 1602.

The memory apparatus 1602 may include a memory cell array 1610 and a voltage generator 1620. The memory cell array 1610 may include a plurality of memory cells and may include the self-selecting memory devices 100 and 300 described above.

The memory controller 1601 may include a processing circuitry such as hardware including a logic circuit, a hardware/software combination such as processor execution software, or any combination thereof. More specifically, the processing circuitry may be, for example, a CPU, an ALU, a digital signal processor, a microcomputer, a field programmable gate array (FPGA), a system-on-chip (SoC), a programmable logic unit, a microprocessor, an application-specific integrated circuit (ASIC), or the like, but the disclosure is not limited thereto. The memory controller 1601 may be configured to operate in response to a request from a host (not shown) and may be configured to access the memory apparatus 1602 and control the control operation (e.g., the write/read operation) so that the memory controller 1601 is converted to a special-purpose controller. The memory controller 1601 may generate an address ADD and a command CMD for performing the program/read/erase operations on the memory cell array 1610. In addition, in response to a command from the memory controller 1601, the voltage generator 1620 (e.g., a power circuitry) may generate a voltage control signal for controlling a voltage level of a word line for programming data to the memory cell array 1610 or reading data from the memory cell array 1610.

In addition, the memory controller 1601 may perform a determination operation on data read from the memory apparatus 1602. For example, the number of on-cells and/or the number of off-cells may be determined from data read from the memory cell. The memory apparatus 1602 may provide a pass/fail signal P/F to the memory controller 1601 according to a reading result of the read data. The memory controller 1601 may control the write/read operations of the memory cell array 1610 by referring to the pass/fail signal P/F.

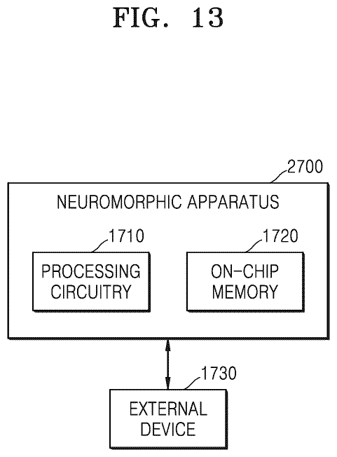

FIG. 13 is a block diagram illustrating a neuromorphic apparatus 2700 and an external device 1730 connected thereto, according to an example embodiment.

Referring to FIG. 13, the neuromorphic apparatus 2700 may include processing circuitry 1710 and/or an on-chip memory 1720. The neuromorphic apparatus 2700 may include the self-selecting memory devices 100 and 300 according to the aforementioned example embodiments.

In some example embodiments, the processing circuitry 1710 may be configured to control functions for driving the neuromorphic apparatus 2700. For example, the processing circuitry 1710 may be configured to control the neuromorphic apparatus 2700 by executing a program stored in the on-chip memory 1720. In some example embodiments, the processing circuitry 1710 may include hardware such as a logic circuitry, a hardware/software combination such as a processor that executes software, or any combination thereof. For example, the processor may include a CPU, a GPU, an application processor (AP) included in the neuromorphic apparatus 2700, an ALU, a digital signal processor, a microcomputer, an FPGA, an SoC, a programmable logic unit, a microprocessor, an ASIC, or the like, but the disclosure is not limited thereto. In some example embodiments, the processing circuitry 1710 may be configured to read/write various data from/to the external device 1730 and/or execute the neuromorphic apparatus 2700 by using the read/written data. In some example embodiments, the external device 1730 may include an external memory and/or a sensor array with an image sensor (e.g., a complementary metal-oxide semiconductor (CMOS) image sensor circuitry).

In some example embodiments, the neuromorphic apparatus 2700 of FIG. 13 may be applied to a machine learning system. The machine learning system may use a variety of artificial neural network organization and processing models, such as a convolutional neural network (CNN), a deconvolution neural network, a recurrent neural network (RNN) optionally including a long short-term memory (LSTM) unit and/or a gated recurrent unit (GRU), a stacked neural network (SNN), a state-space dynamic neural network (SSDNN), a deep belief network (DBN), a generative adversarial network (GAN), and/or a restricted Boltzmann machine (RBM).

Alternatively or additionally, the machine learning system may include other types of machine learning models, for example, combinations including linear and/or logistic regression, statistical clustering, Bayesian classification, decision tree, dimensionality reduction such as principal component analysis, expert systems, and/or ensembles such as random forests. Such machine learning models may be used to provide various services and/or applications. For example, an image classification service, a user authentication service based on biometric information or biometric data, an advanced driver assistance system (ADAS) service, a voice assistant service, an automatic speech recognition (ASR) service, or the like may be executed by the electronic device.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

According to the example embodiments described above, in the self-selecting memory device including the memory layer having OTS characteristics and configured so that the threshold voltage thereof changes according to the polarity and intensity of the voltage applied thereto, information stored in the memory layer may be read by measuring the current value flowing through the memory layer by applying the voltage lower than the set threshold voltage to the memory layer as the read voltage. Accordingly, non-destructive reading is possible because the information recorded on the memory layer is not affected by the reading.

It should be understood that some example embodiments described herein should be considered in a descriptive sense only and not for purposes of limitation. Descriptions of features or aspects within each example embodiment should typically be considered as available for other similar features or aspects in other example embodiments. While one or more embodiments have been described with reference to the figures, it will be understood by those of ordinary skill in the art that various changes in form and details may be made therein without departing from the spirit and scope as defined by the following claims.

What is claimed is:

1. An information reading method of a self-selecting memory device, the self-selecting memory device including a first electrode, a second electrode, and a memory layer therebetween, the memory layer including a chalcogenide-based material, having Ovonic threshold switching characteristics, and configured to have a threshold voltage that changes to a set threshold voltage or a reset threshold voltage higher than the set threshold voltage according to polarity and intensity of a voltage applied to the memory layer, the information reading method comprising:
reading a data value stored in the memory layer by applying, to the memory layer as a read voltage, a voltage lower than the set threshold voltage.

2. The information reading method of claim 1, wherein a level of the read voltage is about 40% to about 90% of a level of the set threshold voltage.

3. The information reading method of claim 2, wherein the level of the read voltage is about 60% to about 80% of the level of the set threshold voltage.

4. The information reading method of claim 1, wherein the reading reads the data value stored in the memory layer by measuring a current flowing through the memory layer at the read voltage.

5. The information reading method of claim 4, wherein, when the current flowing through the memory layer is measured as a relatively high current value, the memory layer is read as set, and when the current flowing through the memory layer is measured as a relatively low current value, the memory layer is read as reset.

6. The information reading method of claim 5, wherein the relatively high current value is 10 times or more the relatively low current value.

7. The information reading method of claim 1, wherein a polarity of the read voltage is positive (+).

8. The information reading method of claim 1, wherein the memory layer includes a chalcogen element including at least one of Se, Te, or S, and at least one of Ge, As, or Sb.

9. The information reading method of claim 8, wherein the memory layer further includes at least one of In, Al, C, B, Sr, Ga, O, N, Si, Ca, or P.

10. An information reading method of a self-selecting memory device, the self-selecting memory device including a first electrode, a second electrode, and a memory layer therebetween, the memory layer including a chalcogenide-based material, having Ovonic threshold switching characteristics, and configured to have a threshold voltage that changes to a set threshold voltage or a reset threshold voltage higher than the set threshold voltage according to polarity and intensity of a voltage applied to the memory layer, the information reading method comprising:
reading a data value stored in the memory layer by applying, to the memory layer as a read voltage, a voltage at a critical point immediately before a slope of a set curve changes rapidly, the voltage at the critical point being lower than the set threshold voltage in a current-voltage characteristic curve for the memory layer.

11. The information reading method of claim 10, wherein a level of the read voltage is about 80% to about 95% of a level of the set threshold voltage.

12. The information reading method of claim 11, wherein the reading reads the data value stored in the memory layer by measuring a value of change of a current flowing through the memory layer at the read voltage.

13. The information reading method of claim 12, wherein, when the value of change of the current measured in the memory layer is a relatively high value, the memory layer is read as set, and when the value of change of the current measured in the memory layer is a relatively low value, the memory layer is read as reset.

14. The information reading method of claim 10, wherein a polarity of the read voltage is positive (+).

15. An information reading method of a self-selecting memory device, the self-selecting memory device including a first electrode, a second electrode, and a memory layer therebetween, the memory layer including a chalcogenide-based material, having Ovonic threshold switching characteristics, and configured to have a threshold voltage that changes to a set threshold voltage or a reset threshold voltage higher than the set threshold voltage according to polarity and intensity of a voltage applied to the memory layer, the information reading method comprising:
reading a data value stored in the memory layer by sequentially applying, to the memory layer as a read voltage, rectangular pulse voltages whose levels gradually increase at a voltage lower than the set threshold voltage.

16. The information reading method of claim 15, wherein, when a certain pulse voltage applied to the memory layer is measured as the set threshold voltage, the memory layer is read as set, and when the certain pulse voltage applied to the memory layer is measured as the reset threshold voltage, the memory layer is read as reset.
